(19) United States
(12) Patent Application Publication
(10) Pub. No.: US 2026/0157193 A1
(43) Pub. Date: Jun. 4, 2026

(54) SEMICONDUCTOR PACKAGE STRUCTURE

(71) Applicant: PANJIT SEMICONDUCTOR (XUZHOU) CO., LTD, Xuzhou (CN)

(72) Inventors: Ting Yu FANG, Xuzhou (CN); Bing WEI, Xuzhou (CN); Cuifeng WAN, Xuzhou (CN); Chung Hsiung HO, Kaohsiung City (TW); Yung-hui WANG, Kaohsiung City (TW); Jeng Sian WU, Kaohsiung City (TW)

(73) Assignee: PANJIT SEMICONDUCTOR (XUZHOU) CO., LTD, Xuzhou (CN)

(21) Appl. No.: 19/040,215

(22) Filed: Jan. 29, 2025

(30) Foreign Application Priority Data
Dec. 4, 2024 (CN) 202411776448.2

(51) Int. Cl. H01L 23/495; H01L 21/48; H01L 21/78; H01L 23/31

(52) U.S. Cl. CPC H10W 70/467; H10W 70/457; H10W 70/458; H10W 74/114; H10P 54/00; H10W 70/042

(57) ABSTRACT

A semiconductor package structure including a lead frame, a die, first and second electrical connection components and an encapsulation layer. The lead frame includes a supporting part and a circuit part spaced apart from each other. The die is disposed on the supporting part of the lead frame and electrically connected to the circuit part of the lead frame. The first electrical connection component includes a conductive adhesive disposed on and electrically connected to the circuit part of the lead frame. The second electrical connection component includes a conductive adhesive disposed on and electrically connected to the supporting part of the lead frame. The encapsulation layer surrounds the die. The conductive adhesives are disposed in the encapsulation layer. Opposite two lateral surfaces of the encapsulation layer expose the conductive adhesives, respectively.

### CROSS-REFERENCE TO RELATED APPLICATIONS

This non-provisional application claims priority under 35 U.S.C. § 119(a) on Patent Application No(s). 202411776448.2 filed in China, on December 4, 2024, the entire contents of which are hereby incorporated by reference.

### TECHNICAL FIELD

The disclosure relates to the technical field of semiconductor, more particularly to a semiconductor package structure.

### BACKGROUND

In general, during the manufacture of a semiconductor package structure, multiple lead frames are firstly formed by an etching process, and then a metal layer made by, for example, Tin is formed on the lead frames.

However, the lead frames are spaced apart and thus electrically insulated from each other. Therefore, in order to form the metal layer made by, for example, Tin on a part of the lead frames by electroplating, a series of complex processes should be performed.

### SUMMARY

The disclosure provides a semiconductor package structure whose manufacturing process allows lead frames spaced apart from each other to be electrically connected, thereby allowing a metal layer to be disposed on the lead frames by electroplating in an effective and convenient manner.

One embodiment of this disclosure provides a semiconductor package structure including a lead frame, a die, a first electrical connection component, a second electrical connection component and an encapsulation layer. The lead frame includes a supporting part and a circuit part spaced apart from each other. The die is disposed on the supporting part of the lead frame and electrically connected to the circuit part of the lead frame. The first electrical connection component includes a conductive adhesive disposed on and electrically connected to the circuit part of the lead frame. The second electrical connection component includes a conductive adhesive disposed on and electrically connected to the supporting part of the lead frame. The encapsulation layer surrounds the die. The conductive adhesive of the first electrical connection component and the conductive adhesive of the second electrical connection component are disposed in the encapsulation layer. Opposite two lateral surfaces of the encapsulation layer expose the conductive adhesive of the first electrical connection component and the conductive adhesive of the second electrical connection component, respectively.

According to the semiconductor package structure disclosed by above embodiments, the opposite two lateral surfaces of the encapsulation layer exposes the first electrical connection component and the second electrical connection component, respectively. Thus, during the manufacture of the semiconductor package structure, the conductive adhesive electrically connects different parts of the lead frame, or electrically connects lead frames that are spaced apart from each other. In this way, the metal layer is allowed to be disposed on the lead frame via electrolytic electroplating in an effective and convenient manner.

Further, since the metal layer is allowed to be disposed on the lead frame via electroplating in an effective and convenient manner, the semiconductor package structure can be manufactured without using the electroless plating involving high cost caused by large volume of chemical plating bath and large amount of plating solution, thereby reducing the manufacture cost of the semiconductor package structure.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a schematic view of a semiconductor package structure according to a first embodiment of the disclosure;

FIGS. 2 to 7 are schematic views showing a manufacture of the semiconductor package structure in FIG. 1;

FIG. 8 is a schematic view of a semiconductor package structure according to a second embodiment of the disclosure; and

FIGS. 9 to 14 are schematic views showing a manufacture of the semiconductor package structure in FIG. 8.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

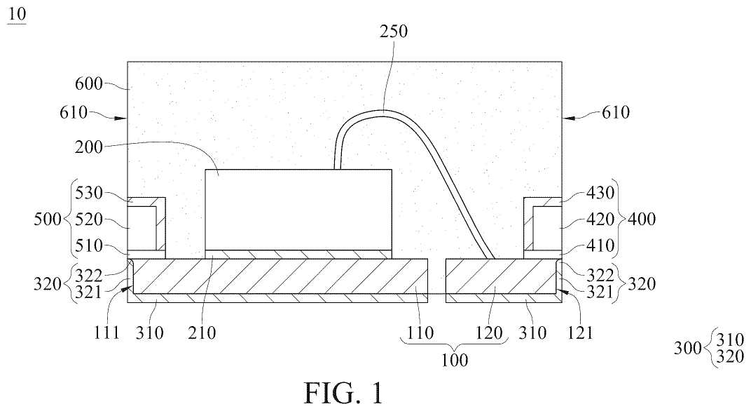

Please refer to FIG. 1. FIG. 1 is a schematic view of a semiconductor package structure 10 according to a first embodiment of the disclosure. In this embodiment, the semiconductor package structure 10 includes, for example, a lead frame 100, a die 200, a lead 250, a metal layer 300, a first electrical connection component 400, a second electrical connection component 500 and an encapsulation layer 600.

In this embodiment, the lead frame 100 includes, for example, a supporting part 110 and a circuit part 120 spaced apart from each other. In this embodiment, for example, the die 200 is disposed on the supporting part 110 via a pad 210, and is electrically connected to the circuit part 120 via the lead 250. The pad 210 is an adhesive layer that may be a conductive adhesive or an electrically insulating adhesive. The lead 250 is connected to, for example, a side of the die 200 located away from the supporting part 110. However, the position where the lead 250 and the die 200 are connected may be adjusted according to the type of the die 200. In addition, the die 200 may be made of semiconductor material such as silicon, silicon carbide or III-V compound semiconductor.

In this embodiment, the metal layer 300 includes a bottom part 310 and two side parts 320, and is made of, for example, Tin, Nickel Gold or the like. At least a part of the metal layer 300 is disposed on a side of the lead frame 100 located away from the die 200. Specifically, the bottom part 310 is disposed on sides of the supporting part 110 and the circuit part 120 of the lead frame 100 located away from the die 200. The bottom part 310 may be understood as including two parts that are disposed on the supporting part 110 and the circuit part 120, respectively. The two side parts 320 are disposed on a lateral surface 111 of the supporting part 110 and a lateral surface 121 of the circuit part 120, respectively. The two side parts 320 each include a flat part 321 and a curved part 322. The flat part 321 connects the bottom part 310 and the curved part 322.

In this embodiment, the first electrical connection component 400 includes a conductive adhesive 410, a non-metal core 420 and a metal film 430. The conductive adhesive 410 is disposed on and electrically connected to the circuit part 120. The metal film 430 is located on a surface of the non-metal core 420. The non-metal core 420 is disposed on a side of the conductive adhesive 410 located away from the circuit part 120.

Similarly, the second electrical connection component 500 includes a conductive adhesive 510, a non-metal core 520 and a metal film 530. The conductive adhesive 510 is disposed on and electrically connected to the supporting part 110. The metal film 530 is located on a surface of the non-metal core 520. The non-metal core 520 is disposed on a side of the conductive adhesive 510 located away from the supporting part 110.

In this embodiment, the non-metal cores 420 and 520 are, for example, electrically insulating. Further, in order to facilitate the acquisition of the material, the non-metal cores 420 and 520 may be made of silicon. Here, the non-metal cores 420 and 520 may be made of electrically insulating material. More specifically, the non-metal cores 420 and 520 may be made of glass, undoped silicon, silicon nitride, silicon oxide or molding compound resin.

Moreover, in this embodiment, the metal films 430 and 530 and the lead frame 100 may be made of the same material, such as copper, or may be at least partially made by copper.

Also, in this embodiment, the conductive adhesives 410 and 510 are, for example, metal conductive adhesives.

The encapsulation layer 600 surrounds the die 200. The first electrical connection component 400 and the second electrical connection component 500 are disposed in the encapsulation layer 600. In other words, the conductive adhesive 410, the non-metal core 420 and the metal film 430 are disposed in the encapsulation layer 600, and the conductive adhesive 510, the non-metal core 520 and the metal film 530 are disposed in the encapsulation layer 600. Additionally, two opposite lateral surfaces 610 of the encapsulation layer 600 expose the conductive adhesive 410, the non-metal core 420 and the metal film 430 of the first electrical connection component 400 and the conductive adhesive 510, the non-metal core 520 and the metal film 530 of the second electrical connection component 500, respectively. In other words, the conductive adhesive 410, the non-metal core 420 and the metal film 430 and the conductive adhesive 510, the non-metal core 520 and the metal film 530 are exposed to the outside from the two opposite lateral surfaces 610 of the encapsulation layer 600, respectively.

Note that the metal film 430 being located on the surface of the non-metal core 420 may be understood as the metal film 430 being located on the surface of the non-metal core 420 except a part of the said surface that is exposed on the lateral surface 610. The relationship between the metal film 530 and the non-metal core 520 may be understood in a similar manner, and thus the repeated descriptions are omitted.

In addition, the encapsulation layer 600 may be made of organic composite material, epoxy composite material, macromolecule composite material, polymer composite material or other epoxy molding compounds. For example, the encapsulation layer 600 may be an epoxy resin encapsulation layer.

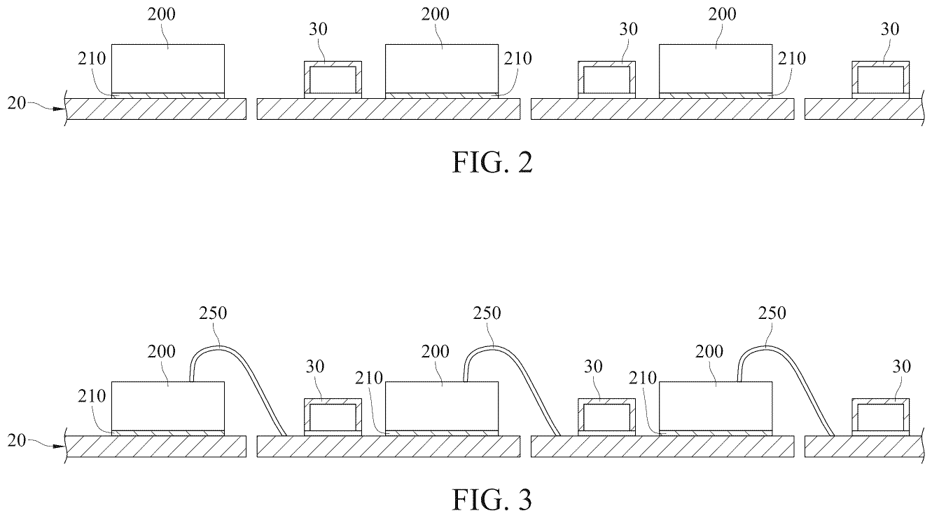

Please refer to FIGS. 2 to 7. FIGS. 2 to 7 are schematic views showing a manufacture of the semiconductor package structure 10 in FIG. 1. As shown in FIG. 2, a metal layer 20 is provided, and a plurality of electrical connection components 30 and a plurality of dies 200 are disposed on the metal layer 20. The dies 200 are disposed on the metal layer 20 via, for example, pads 210.

As shown in FIG. 3, the dies 200 are electrically connected to the metal layer 20 via a plurality of leads 250, respectively.

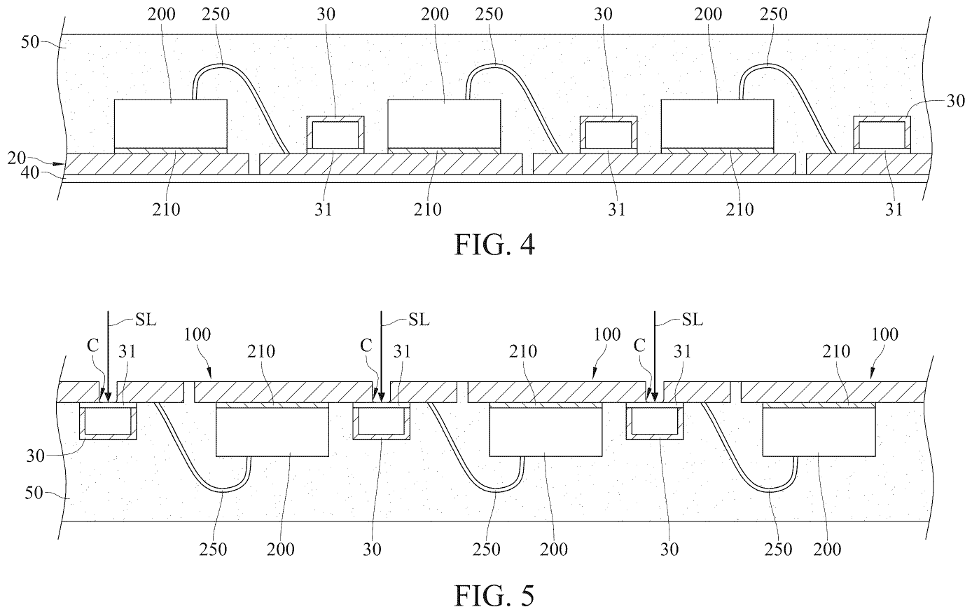

As shown in FIG. 4, the metal layer 20 is transferred to a temporary carrier 40, and an encapsulation body 50 is formed on the dies 200 and the metal layer 20. The temporary carrier 40 is, for example, a tape or other types of substrates whose surface is adhesive. The formation of the encapsulation body 50 may be implemented by injection molding, thermoforming or the like.

As shown in FIGS. 4 and 5, the temporary carrier 40 is removed, and then a first cutting process is performed to, for example, divide the metal layer 20 into a plurality of lead frames 100 by a first cutter (not shown) along a cutting direction SL. Also, due to the outline of the first cutter, a corner C is formed on a surface of an edge of the lead frame 100 adjoining the conductive adhesive 31 by the first cutting process. For example, the depth of the first cutting process is equal to the thickness of the lead frame 100 so that the conductive adhesive 31 is exposed from the opening formed by the first cutting process, or is larger than the thickness of the lead frame 100 so that a part of the conductive adhesive 31 of the electrical connection component 30 is cut. Note that in other embodiments, an entire of the conductive adhesive of the electrical connection component and a part of the non-metal core of the electrical connection component may be cut. In still other embodiments, the step shown in FIG. 5 may be performed by an etching process.

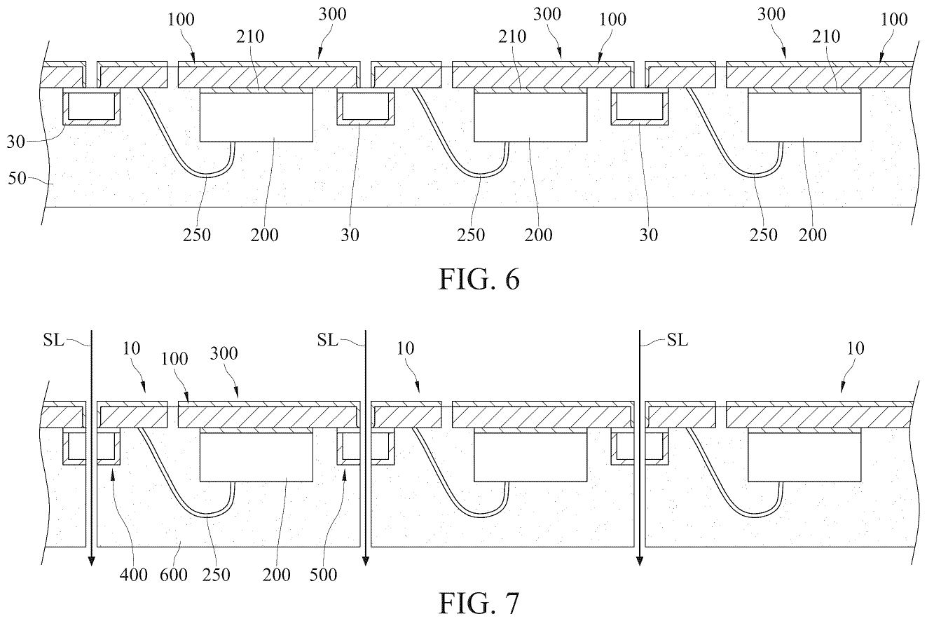

As shown in FIG. 6, a metal layer 300 is formed on the lead frames 100 by, for example, electroplating.

As shown in FIGS. 6 and 7, the electrical connection component 30 and the encapsulation body 50 are cut by a second cutter along the cutting direction SL, so as to form a plurality of semiconductor package structures 10 as shown in FIG. 1. A diameter of the second cutter is smaller than a diameter of the first cutter.

Please refer to FIGS. 1 and 6. The lateral surface 610 of the encapsulation layer 600 exposes the first electrical connection component 400 or the second electrical connection component 500. Thus, during the manufacture of the semiconductor package structure 10, the first electrical connection component 400 or the second electrical connection component 500 electrically connects different parts of the lead frame 100 in FIG. 6, or electrically connects lead frames 100 in FIG. 6 that are spaced apart from each other. In this way, the metal layer 300 is allowed to be disposed on the lead frame 100 via electroplating in an effective and convenient manner.

Further, since the metal layer 300 is allowed to be disposed on the lead frame 100 via electroplating in an effective and convenient manner, the semiconductor package structure 10 can be manufactured without using the electroless plating involving high cost caused by large volume of chemical plating bath and large amount of plating solution, thereby reducing the manufacture cost of the semiconductor package structure 10.

Moreover, the metal layer 300 made of, for example, Tin is disposed by electroplating, and the metal layer 300 formed by electroplating has the curved part 322 connected to the conductive adhesive 31 in FIG. 6. Thus, it is ensured that the height of the fillet on the metal layer 300 is larger than or equal to the thickness of the lead frame 100. That is, it is ensured that the curved part 322 are arranged over an entire of the lateral surface 111 of the supporting part 110 or an entire of the lateral surface 121 of the circuit part 120. Accordingly, the detection performed on the fillet by optical means (e.g., Automated Optical Inspection) is facilitated.

Moreover, the aforementioned structural features may be applied to achieve the aforementioned effect without modifying the overall size of the semiconductor package structure 10 in this embodiment, which allows the semiconductor package structure 10 to meet its original specification.

Additionally, the first electrical connection component 400 and the second electrical connection component 500 include the conductive adhesives 410 and 510, the non-metal cores 420 and 520 and the metal films 430 and 530. Therefore, in the cutting process shown in FIG. 5, the reliability for the first electrical connection component 400 and the second electrical connection component 500 to electrically connect different parts of the lead frame 100 is ensured regardless of whether the conductive adhesives 410 and 510 are entirely cut, which further facilitates the cutting process shown in FIG. 5. However, the disclosure is not limited thereto. In other embodiments, the first electrical connection component and the second electrical connection component may merely include the conductive adhesives 410 and 510 without including the non-metal cores 420 and 520 and the metal films 430 and 530. In such embodiments, as long as the conductive adhesives 410 and 510 are ensured not to be entirely cut in the cutting process shown in FIG. 5, the conductive adhesives 410 and 510 can electrically connect different parts of the lead frame 100.

Furthermore, since the first electrical connection component 400 and the second electrical connection component 500 are not copper blocks, rough edges or uneven edges are prevented from being generated on the first electrical connection component 400 and the second electrical connection component 500. Thus, the first electrical connection component 400 and the second electrical connection component 500 are prevented from contacting the die 200, which achieves a high component density by facilitating the shortening of the horizontal distances between the first electrical connection component 400, the second electrical connection component 500 and the die 200.

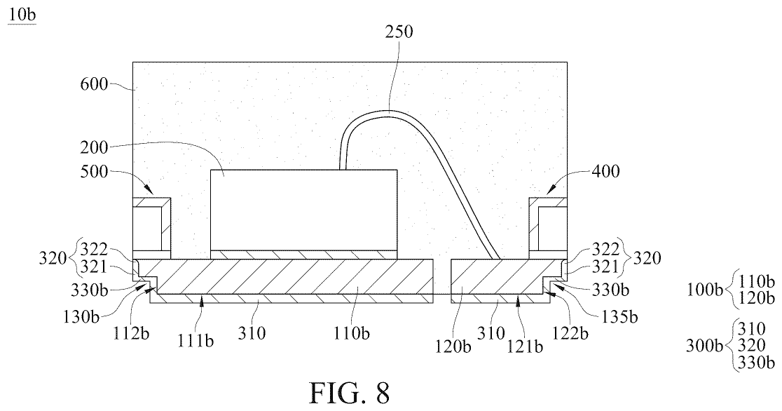

Please refer to FIG. 8. FIG. 8 is a schematic view of a semiconductor package structure 10b according to a second embodiment of the disclosure. In this embodiment, the semiconductor package structure 10b includes, for example, a lead frame 100b, the die 200, the lead 250, a metal layer 300b, the first electrical connection component 400, the second electrical connection component 500 and the encapsulation layer 600. The detailed structures and connection relationships of the die 200, the lead 250, the first electrical connection component 400, the second electrical connection component 500 and the encapsulation layer 600 may be understood by referring to the aforementioned descriptions of corresponding components of the semiconductor package structure 10, and thus are not repeatedly described.

In this embodiment, the lead frame 100b has two notches 130b and 135b. The notch 130b is located on a position where a bottom surface 111b and a lateral surface 112b of the supporting part 110b are connected so that the supporting part 110b has an edge that is in a step shape. The bottom surface 111b, for example, faces away from the die 200 and is connected to the lateral surface 112b. The notch 135b is located on a position where a bottom surface 121b and a lateral surface 122b of the circuit part 120b are connected so that the circuit part 120b has an edge that is in a step shape. The bottom surface 121b, for example, faces away from the die 200 and is connected to the lateral surface 122b.

The metal layer 300b includes a bottom part 310, two side parts 320 and two step parts 330b, and is made of Tin, Nickel Gold or the like. Specifically, the two step parts 330b of the two side parts 320 are located in the two notches 130b and 135b, respectively. Two flat parts 321 of the two side parts 320 are connected to the bottom part 310 via the two step parts 330b, respectively.

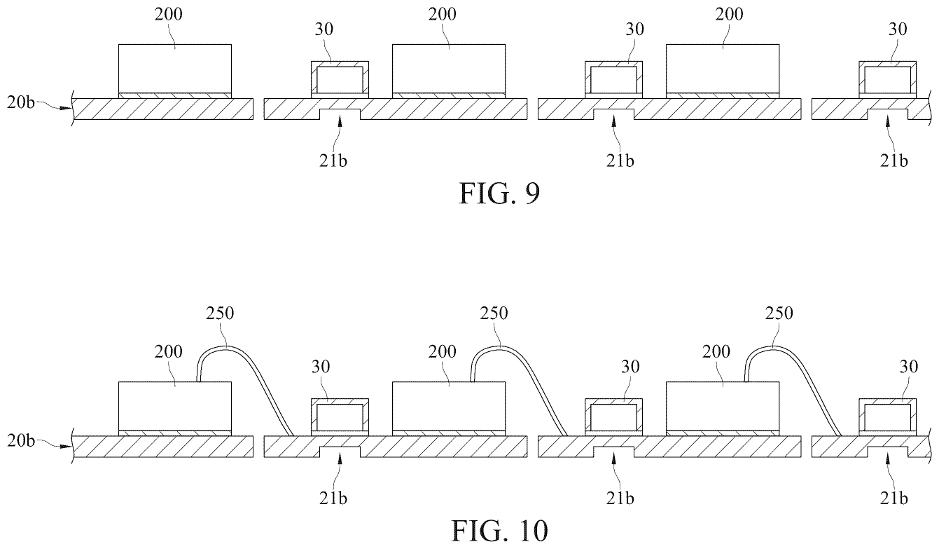

Please refer to FIGS. 9 to 14. FIGS. 9 to 14 are schematic views showing a manufacture of the semiconductor package structure 10b in FIG. 8. As shown in FIG. 9, a metal layer 20b is provided, and a plurality of electrical connection components 30 and a plurality of dies 200 are disposed on the metal layer 20b. The metal layer 20b has a plurality of recesses 21b. The die 200 is disposed on the metal layer 20b via, for example, pads 210.

As shown in FIG. 10, the dies 200 are electrically connected to the metal layer 20b via a plurality of leads 250.

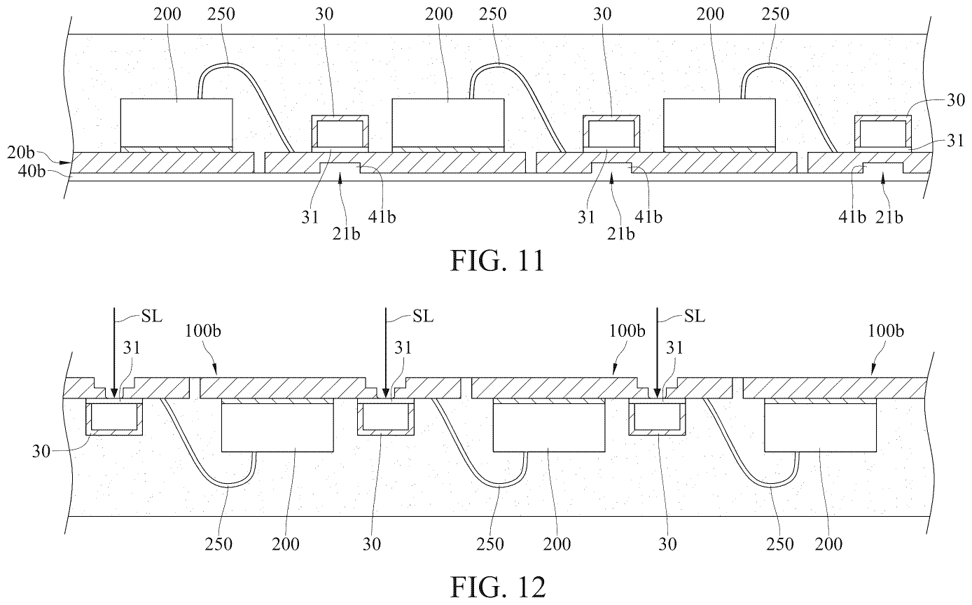

As shown in FIG. 11, the metal layer 20b is transferred to a temporary carrier 40b, and an encapsulation body 50 is formed on the dies 200 and the metal layer 20b. The temporary carrier 40b is, for example, a tape or other types of substrates whose surface is adhesive. Also, the temporary carrier 40b has, for example, a plurality of protrusions 41b located in the recesses 21b, respectively. The formation of the encapsulation body 50 may be implemented by injection molding, thermoforming or the like.

As shown in FIGS. 11 and 12, the temporary carrier 40b is removed, and then a first cutting process is performed to, for example, divide the metal layer 20b into a plurality of lead frames 100b by the first cutter (not shown) along the cutting direction SL and cut a part of the conductive adhesive 31 of the electrical connection component 30 or cut an entire of the metal layer 20b without cutting the conductive adhesive 31. Note that in other embodiments, for example, an entire of the conductive adhesive of the electrical connection component and a part of the non-metal core of the electrical connection component may be cut.

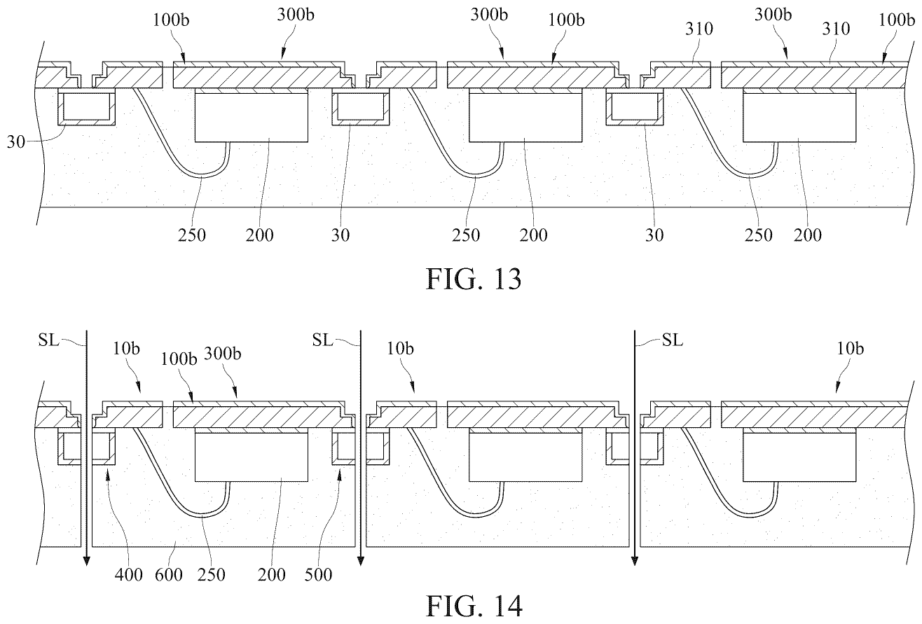

As shown in FIG. 13, the metal layer 300b is formed on the lead frames 100b by, for example, electroplating.

As shown in FIGS. 13 and 14, a second cutting process is then performed to, for example, cut the electrical connection component 30 and the encapsulation body 50 along the cutting direction SL to form a plurality of semiconductor package structures 10b as shown in FIG. 8.

According to the semiconductor package structure disclosed by above embodiments, the opposite two lateral surfaces of the encapsulation layer exposes the first electrical connection component and the second electrical connection component, respectively. Thus, during the manufacture of the semiconductor package structure, the conductive adhesive electrically connects different parts of the lead frame, or electrically connects lead frames that are spaced apart from each other. In this way, the metal layer is allowed to be disposed on the lead frame via electroplating in an effective and convenient manner.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A semiconductor package structure, comprising:
a lead frame, comprising a supporting part and a circuit part spaced apart from each other;
a die, disposed on the supporting part of the lead frame and electrically connected to the circuit part of the lead frame;
a first electrical connection component, comprising a conductive adhesive disposed on and electrically connected to the circuit part of the lead frame;
a second electrical connection component, comprising a conductive adhesive disposed on and electrically connected to the supporting part of the lead frame; and
an encapsulation layer, surrounding the die, wherein the conductive adhesive of the first electrical connection component and the conductive adhesive of the second electrical connection component are disposed in the encapsulation layer, and opposite two lateral surfaces of the encapsulation layer expose the conductive adhesive of the first electrical connection component and the conductive adhesive of the second electrical connection component, respectively.

2. The semiconductor package structure according to claim 1, wherein the first electrical connection component further comprises a non-metal core and a metal film, the non-metal core is disposed on a side of the conductive adhesive of the first electrical connection component located away from the lead frame, and the metal film is located on a surface of the non-metal core except a part of the surface of the non-metal core that is exposed on one of the two lateral surfaces of the encapsulation layer.

3. The semiconductor package structure according to claim 1, wherein the second electrical connection component further comprises a non-metal core and a metal film, the non-metal core is disposed on a side of the conductive adhesive of the second electrical connection component located away from the lead frame, and the metal film is located on a surface of the non-metal core except a part of the surface of the non-metal core that is exposed on another one of the two lateral surfaces of the encapsulation layer.

4. The semiconductor package structure according to claim 2, wherein the conductive adhesive of the first electrical connection component, the non-metal core and the metal film are disposed in the encapsulation layer, and the one of the two lateral surfaces of the encapsulation layer exposes the conductive adhesive of the first electrical connection component, the non-metal core and the metal film.

5. The semiconductor package structure according to claim 2, wherein the non-metal core is electrically insulating.

6. The semiconductor package structure according to claim 2, wherein the non-metal core is made of glass, undoped silicon, silicon nitride, silicon oxide or molding compound resin.

7. The semiconductor package structure according to claim 2, wherein the metal film and the lead frame are made of a metallic material.

8. The semiconductor package structure according to claim 1, further comprising a metal layer, wherein at least a part of the metal layer is disposed on a side of the lead frame located away from the die.

9. The semiconductor package structure according to claim 8, wherein the metal layer comprises a bottom part and at least one side part, the bottom part is disposed on the side of the lead frame located away from the die, and the at least one side part is disposed on a lateral surface of the lead frame.

10. The semiconductor package structure according to claim 9, wherein the at least one side part comprises two side parts, one of the two side parts is disposed on a lateral surface of the supporting part, and another one of the two side parts is disposed on a lateral surface of the circuit part.

11. The semiconductor package structure according to claim 10, wherein the two side parts of the metal layer each comprises a flat part and a curved part, in each of the two side parts, the flat part connects the bottom part and the curved part, and the curved part is connected to the conductive adhesive of the first electrical connection component or the conductive adhesive of the second electrical connection component.

12. The semiconductor package structure according to claim 11, wherein the curved part of each of the two side parts is arranged over an entire of the lateral surface of the supporting part or an entire of the lateral surface of the circuit part.

13. The semiconductor package structure according to claim 1, wherein the lead frame has at least one notch located on a position where a bottom surface and a lateral surface of the lead frame are connected.

14. The semiconductor package structure according to claim 13, wherein the at least one notch is located on a position where a bottom surface and a lateral surface of the supporting part are connected so that the supporting part has an edge in a step shape.

15. The semiconductor package structure according to claim 13, wherein the at least one notch is located on a position where a bottom surface and a lateral surface of the circuit part are connected so that the circuit part has an edge in a step shape.

16. The semiconductor package structure according to claim 13, wherein the metal layer comprises a bottom part, at least one side part and at least one step part, and each of the side part has a step part located in the notch, respectively.

17. The semiconductor package structure according to claim 16, wherein the side part of the metal layer comprises a flat part and a curved part, the flat part connects the bottom part and the curved part, the curved part is connected to the conductive adhesive, and the flat part of the side part is connected to the bottom part via the step part.

18. The semiconductor package structure according to claim 1, further comprising a lead, wherein the die is electrically connected to the circuit part of the lead frame via the lead, and the lead is not connected to the first electrical connection component on the circuit part.

19. The semiconductor package structure according to claim 1, wherein the conductive adhesive of the first electrical connection component and the conductive adhesive of the second electrical connection component are metal conductive adhesives.

20. The semiconductor package structure according to claim 1, wherein a surface of the lead frame adjoining the conductive adhesive has a corner formed by a cutting process.
